(19) United States
(12) Patent Application Publication
(10) Pub. No.: US 2014/0034891 A1
(43) Pub. Date: Feb. 6, 2014

(54) SEMICONDUCTOR MEMORY STRUCTURE AND ITS MANUFACTURING METHOD THEREOF

(71) Applicants: Pengfei Wang, Shanghai (CN); Xi Lin, Shanghai (CN); Qingqing Sun, Shanghai (CN); Wei Zhang, Shanghai (CN)

(72) Inventors: Pengfei Wang, Shanghai (CN); Xi Lin, Shanghai (CN); Qingqing Sun, Shanghai (CN); Wei Zhang, Shanghai (CN)

(73) Assignee: FUDAN UNIVERSITY, Shanghai (CN)

(21) Appl. No.: 13/376,994

(22) PCT Filed: Aug. 15, 2011
(86) PCT No.: PCT/CN11/01352

§ 371 Date: Dec. 8, 2011

(30) Foreign Application Priority Data
Apr. 22, 2011 (CN) 201110101360.7

(51) Int. Cl. H01L 27/24

(52) U.S. Cl. CPC H01L 27/2463
USPC 257/2; 438/238

(57) ABSTRACT

The present invention belongs to the technical field of microelectronic devices, specifically relates to a semiconductor memory structure and its manufacturing method thereof. The semiconductor memory structure which carries out erasing, writing and reading operation on the phase change memory or the resistance change memory through a tunneling field-effect transistor is formed, for one hand, the high current passed through the tunneling field-effect transistor when the p-n junction the biased positively, meeting the high current requirements for erasing of and writing of the phase change memory and the resistance change memory, and on the other hand, Vertical structure of the field-effect transistor can greatly improve the density of memory devices arrays. The present invention also discloses a method, which is very suitable for the memory chips, for the manufacturing of the semiconductor memory structure using self-aligned process.

### FIELD OF INVENTION

The present invention belongs to the technical field of microelectronic devices, specifically relates to a semiconductor memory structure and its manufacturing method thereof, and more especially, to a semiconductor memory structure which controls the phase change memory and the resistance change memory through a tunneling field-effect transistor, and its manufacturing method thereof.

### BACKGROUND OF THE INVENTION

Flash floating gate memory is a semiconductor memory device capable of realizing non-volatile data saving function. FIG. 1 is the equivalent circuit diagram of a semiconductor memory device in the prior art. As shown in FIG. 1, the memory device consists of a transistor 313 and a storage unit 314 which are connected in series between a bit line 315 and a source potential 312, and a word line 311 is used to control the switch of the transistor 313. To access the data stored in the storage unit 314, a positive voltage is imposed on word line 311 to turn on the transistor 313 and starts the transistor 313. At the same time, a voltage on the bit line 315 is imposed on the storage unit 314, which causes the current to flow through the storage unit 314 and the transistor 313. The data stored in the storage unit 314 can be read based on the output current value.

With the development of integrated circuit device technology, the size of semiconductor devices keeps shrinking, making the design of integrated circuits move toward the trend of integration of System on Chip (SOC). The key technology of the realization of SOC is the integration of the on-chip memory featuring low power consumption, high density and fast access speed. The existing technology of integrated circuit devices is about 30 nm, but the traditional flash floating gate memory is very difficult to be scaled down to the size below 30 nm because of the problems such as high coupling ratio and high voltage. Therefore, the development of new-type flash floating gate memory is becoming the hot point of the present research. Both the phase change memory and resistance change memory can be used as a new-type memory.

The phase change memory stores data by using the tremendous conductivity difference of the chalcogenide in either a crystalline state or amorphous state. The phase change in chalcogenide may show a reversible phase change phenomenon when transforming to the crystalline phase from the amorphous phase. Materials are in a highly disordered state when they are in an amorphous phase, without the presence of any crystalline grid structure, And they have high impedance and high reflectivity in this state. On the contrary, in the crystalline phase, materials have an ordered crystalline structure and low impedance, low reflectivity. The phase change memory makes use of the impedance difference between two phases. The intense heat produced by the injection of current can cause the phase change of materials. The properties of the phase changed materials are determined by the injected current, voltage and the operation time, Compared to the traditional Flash floating gate memory, the phase change memory has faster writing and erasing speed and better scaling.

The data reading and writing of the resistance change memory is realized by reading or changing the resistance of resistance change materials. The resistance change materials usually have two states: high resistance and low resistance. Just like the storage principals of most semiconductor memory in the prior art, the resistance change memory stores data by changing the resistivity of the materials themselves rather than the quantity of charge stored in a capacitive structure. Since the resistivity of materials themselves is not related to the size of them, theoretically, the storage performance of the resistance change memory will not be degraded with the reduction of the sizes of devices. This makes the potential integration ability of resistance change memory much better than the traditional Flash floating gate memory. On the other hand, with the simple structure of the resistance change memory, it is easy to realize the integration with the existing CMOS production techniques.

However, both the phase change memory and the resistance change memory require relatively high erasing current, so a special array storage device is required for erasing.

### BRIEF SUMMARY OF THE INVENTION

The present invention aims at providing a semiconductor storage structure which can carry out reading, writing and other operations on a semiconductor memory by using a low current,

The semiconductor structure provided by the present invention comprises at least one resistance-variable storage unit and one tunneling field-effect transistor structure which is used to operate the semiconductor memory; wherein, the said tunneling field-effect transistor includes at least one source electrode, one drain electrode, one lightlychannel region and one gate electrode, the gate of the said tunneling field-effect transistor is connected to the word line, the source electrode is connected to the source line, the both ends of the variable resistance element are connected to the bit line and the drain electrode of the said tunneling field-effect transistor respectively.

The drain region of the said tunneling field-effect transistor is located on the top of a vertical mesa, The mesa is made of semiconductor substrate material, the said source electrode is located inside the substrate outwards extended from bottom of the said mesa structure, the said lightly doped channel region is between the drain electrode and the source electrode, the said gate electrode shall cover the part below the lightly-doped channel region of the platform structure to control the current passing through the source electrode and the drain electrode in the channel region.

The said resistance-variable storage unit, made of phase change materials or resistance change materials, is connected with the source electrode or the drain electrode of the said tunneling field-effect transistor. The gate electrode of the said tunneling field-effect transistor can control the current passing through the said storage unit to realize the reading and writing operation of the said storage unit.

The said semiconductor substrate is made of monocrystalline polycrystalline silicon or silicon-on-insulator (SOD. The stack of the said gate electrode comprises at least one conducting layer and one insulating layer for isolating the said conducting layer from the said semiconductor substrate. The said conducting layer is made of polycrystalline silicon, amorphous silicon, tungsten metal, titanium nitride, tantalum nitride or metal silicide, while the said insulating layer is made of SiO₂, HfO₂, HfSiO, HfSiON, SiON, Al₂O₃ or the mixture of some of them. Moreover, the said conducting layer of the gate electrode forms a sidewall structure by surrounding the lightly-doped channel region vertically.

Since the tunneling field-effect transistor is with a gate-controlled diode structure, high current can pass through it when the p-n junction of the tunneling field-effect transistor is biased positively, thus meeting the high current requirements for writing of the phase change memory and the resistance change memory.

The present invention also provides a manufacturing method of the semiconductor memory structure above, comprising the following steps: provide a semiconductor substrate; implant doping ions into the said substrate to form a first doped type region; form a first layer of insulating film; form a active columnar region by etching the first layer of insulating film and the semiconductor substrate; form a high-k material dielectric layer, a conducting layer and a polycrystalline silicon layer through settlement in order; form a sidewall and an opening for ions injection by etching the polycrystalline silicon layer; implant ions to form a second doped type region; etch the high-k material dielectric layer, the conducting layer and the polycrystalline silicon layer, and remove the rest part of the first layer of insulating film by etching; deposit an oxide dielectric layer and form a through-hole structure via etching it; form a resistance change material film and a metal layer through settlement in turn and form a bit line through etching the resistance change material film and the metal layer.

The said semiconductor substrate is made of monocrystalline polycrystalline silicon or silicon-on-insulator (SOI). The first doped type is n type, the second doped type is p type, or the reverse type respectively.

The said first layer of insulating film is made of SiO₂, Si₃N₄ or the mixture of insulating materials of them, the said resistance change material film is ZnO₂, CuO, low-k material or GeSbTe material, and the metal layer is made of TiN, Ti, Ta or TaN.

With the manufacturing method provided by the present invention, the gate electrode, the drain electrode and the source electrode can align by themselves. Moreover, since the depth of the first doping is lower than the height of the columnar active region, the gate length of the tunneling field-effect transistor can be controlled by changing the etching conditions. This method not only simplifies the manufacturing procedure of the memory devices, but also makes the manufacturing process more stable.

### BRIEF DESCRIPTION OF THE SEVERAL VIEWS OF THE DRAWINGS

FIG. 1 is the equivalent-circuit diagram of a semiconductor memory device in the prior art.

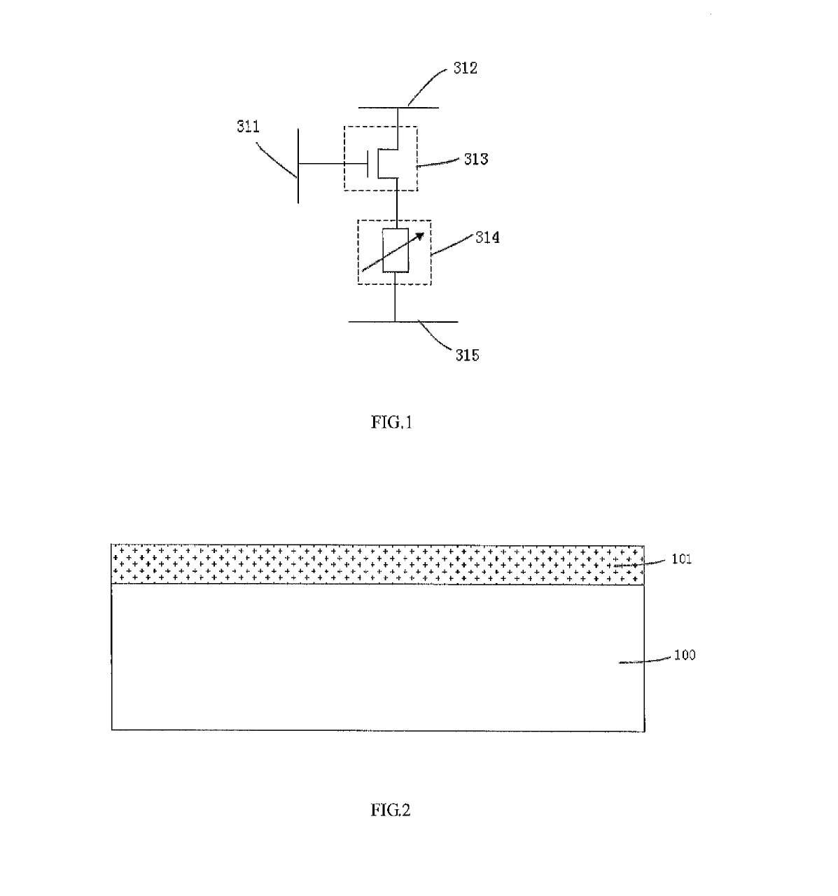

FIGS. 2, 4, 5, 7, 8, 10, 12, 13 and 15 are the cross-sectional views of the implementation techniques of a semiconductor memory device provided by the present invention.

FIG. 3 is the top view when the first layer of insulating film and the semiconductor substrate form a columnar active region structure by etching.

FIG. 6 is the top view when the polycrystalline silicon layer is etched.

FIG. 9 is the top view when the gate dielectric layer and the first layer of insulating film are etched.

FIG. 11 is the top view when the oxide dielectric layer is etched.

FIG. 14 is the top view when the resistance change material film and metal layer is etched.

FIG. 16 is the equivalent circuit diagram of the semiconductor memory device shown in FIG. 15.

### DETAILED DESCRIPTION OF THE INVENTION

An exemplary embodiment of the present invention will be detailed hereinafter by reference to the drawings. In the drawings, for better illustration, the thickness between the layers and the regions is magnified, but the sizes shown do not represent the actual sizes. Although these drawings have not reflect the actual sizes of the devices accurately, they completely reflect the mutual position of the regions and the composition structures, especially the upper-lower and adjacent relations between the composition structures.

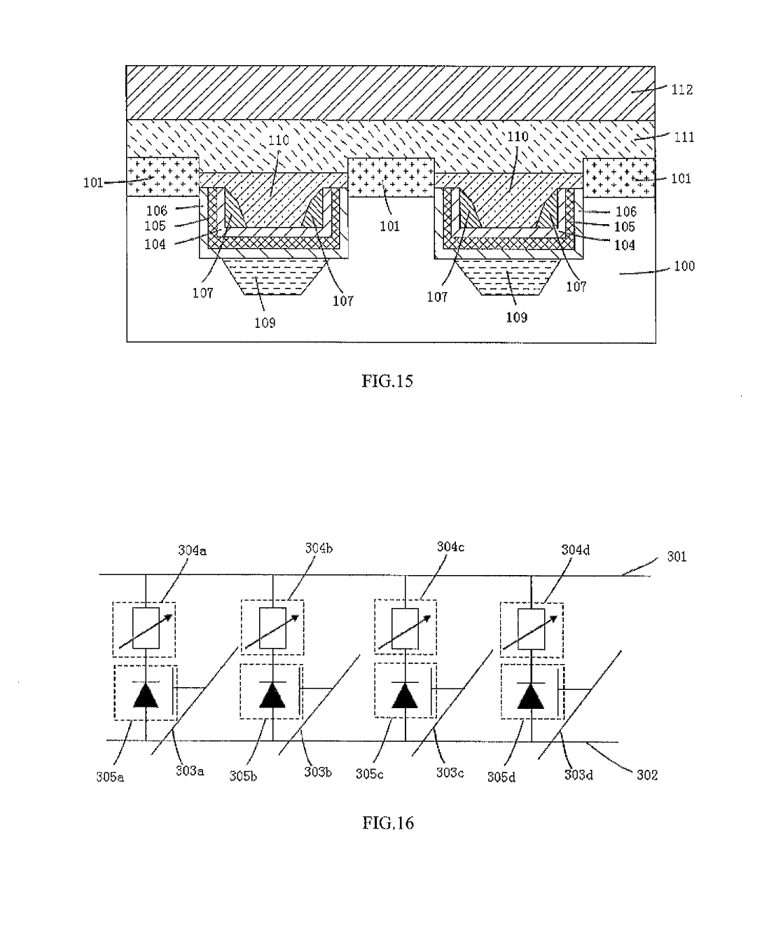

FIG. 16 is the circuit diagram of the parallel connected semiconductor memories provided by the present invention. It can be concluded that, the semiconductor memory structure provided by the present invention comprises at least one resistance-variable storage unit and one tunneling field-effect transistor structure used to operate the semiconductor memory. The said tunneling field-effect transistor comprises at least one source electrode, one drain electrode, one lightly-doped channel region and one gate electrode. By taking the semiconductor memory structure shown on the leftmost side of FIG. 16 as an example, wherein the said semiconductor memory consists of the tunneling field-effect transistor 305a and variable resistance element 304a, in the operation of the formed semiconductor chip, generally, the gate electrode of the said tunneling field-effect transistor will be connected to the word line 303a, the source electrode will be connected to the source line 302, the both ends of the variable resistance 304a will be connected to the drain electrode of the tunneling field-effect transistor 305a and the bit line 301, thus the current passing through the variable resistance 304a can be controlled by controlling the tunneling field-effect transistor 305a.

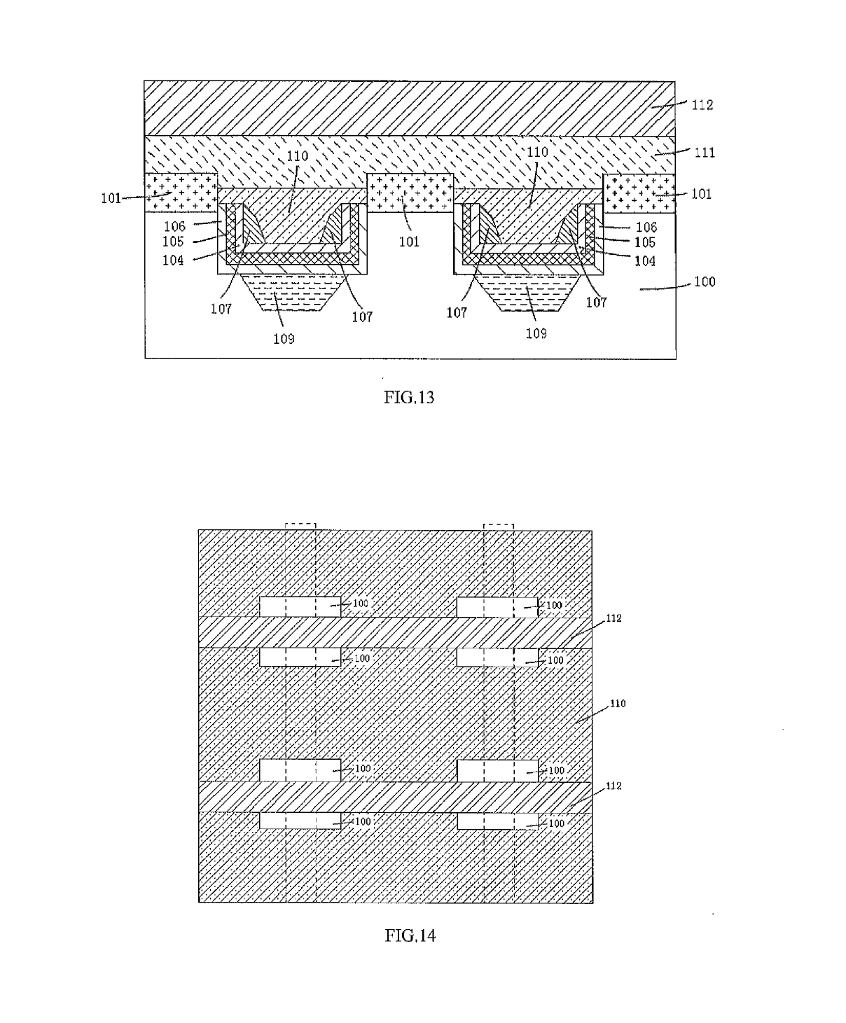

FIG. 15 is the cross-sectional view along the bit line 112 shown in FIG. 14. It can be concluded that, the drain region 101 of the said tunneling field-effect transistor is located on the top of a mesa (platform structure vertical to the horizontal surface, the platform structure is made of the materials similar to those used by the semiconductor substrate 100, the said source electrode 109 is located inside the substrate extended outwards from the bottom of the said platform structure, the said lightly-doped channel region, between the said drain electrode 101 and the said source electrode 109, can be regarded as the doping of the original substrate, the said gate electrode 107 shall cover the part below the low-doped channel region of the platform to control the current passing through the source electrode and the drain electrode in the channel region.

The said resistance-variable storage unit 111, made of phase change materials or resistance change materials, is connected with the drain electrode of the said tunneling field-effect transistor. As shown in FIG. 15, the resistance-variable storage unit is 111 and is between the drain electrode of the tunneling field-effect transistor and the bit line 112. When there is a voltage difference between the drain electrode 101 and the bit line 112, a current may pass through the resistance-variable storage unit 111. The gate electrode 107 of the said tunneling field-effect transistor can control the current passing through the said storage unit 111 to realize the reading and writing operation of the storage unit.

The said semiconductor substrate is made of monocrystalline silicon, polycrystalline silicon or silicon-on-insulator (SOI). The gate stack comprises at least one conducting layer and one insulating layer for isolating the said conducting layer from the said semiconductor substrate. The said conducting layer is made of polycrystalline silicon, amorphous silicon, tungsten metal, titanium nitride, tantalum nitride or metal silicide, while the said insulating layer is made of SiO₂, HfO₂, HfSiO, HfSiON, SiON, Al₂O₃ or the mixture of some of them. Moreover, the said conducting layer of the gate electrode forms a sidewall structure by surrounding the low-doped channel region vertically.

The said resistance-variable storage unit, made of phase change materials or resistance change materials, is connected with the source electrode or the drain electrode of the said tunneling field-effect transistor. Thus the gate electrode of the said tunneling field-effect transistor can control the current passing through the said storage unit.

Since the tunneling field-effect transistor is with a gate-controlled diode structure, high current can pass through it when the p-n junction of the tunneling field-effect transistor is biased positively to meet the high current requirement for writing of the phase change memory and the resistance change memory. The traditional devices using a MOSFET (metal-oxide-semiconductor field-effect transistor) in the same size can hardly reach the high current requirement. Here are the embodiments of the manufacturing method of the new-type semiconductor memory put forward by the present invention.

The drawings show the schematic views of ideal embodiments for the present invention, The embodiments of the present invention shall include all the shapes achieved, such as the deviation caused by manufacturing, rather than the specific shape shown in the drawings only, For example, the curves obtained by etching are usually bent and round, but in the embodiments of the present invention, they are all indicated by a rectangle. The indications in the drawings are illustrative only, but they shall not be regarded as the limitation to the present invention. The term “substrate” used in the following description can be understood as that including the semiconductor substrate in the process of manufacturing and also other film layers made on them.

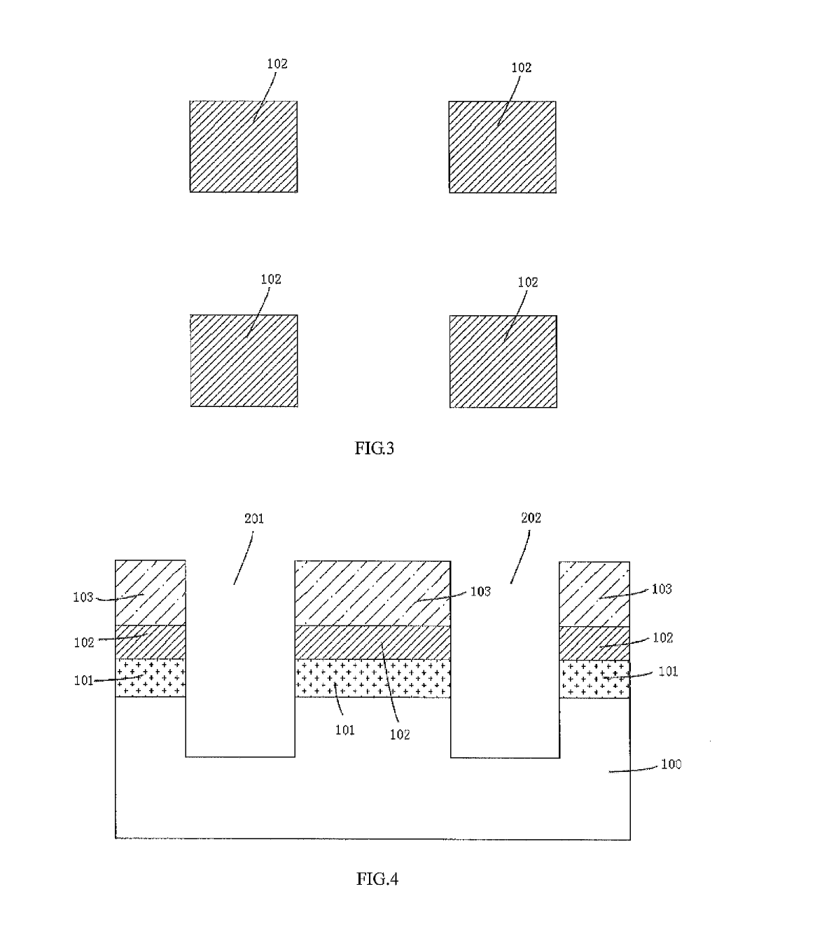

As shown in FIG. 2, provide a semiconductor substrate 100 and then carry out n-type iron injection to form the doped region 101.

Afterwards, form a film 102 and a film 103 on the semiconductor substrate provided through settlement in turn, such as an photo-resist layer, and then etch part of the film 103 and 102, form an opening 201 and an opening 202 in the semiconductor substrate, as shown in FIG. 4, in this way, the columnar active region is formed. Film 102 is SiO₂, Si₃O₄ or the insulating material of their mixture, and the film 103 is photo-resist layer.

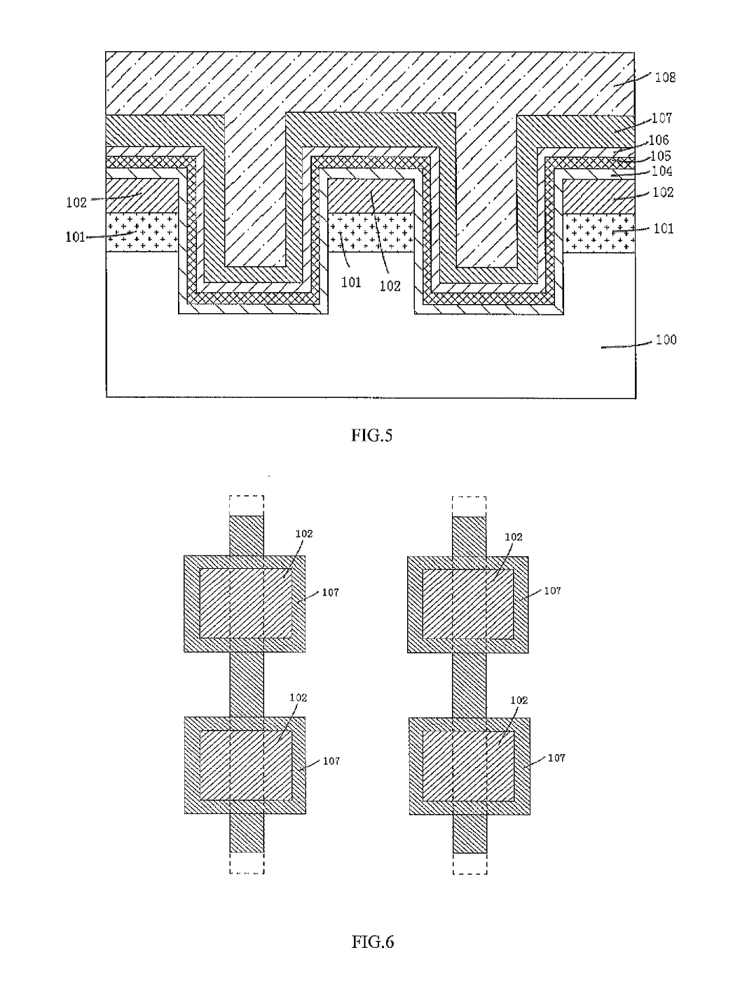

It shall be noted that, during the etching mentioned above, the doped region 101 formed previously will also be etched, so the grid length of the tunneling field-effect transistor can be controlled through changing the etching conditions. FIG. 3 is the top view when carrying out the etching.

Next, remove the film 103, and then form film 104, 105, 106, 107 and 108 through deposition in turn, the film 104 is, for example, SiO₂, the film 105 is a high-k dielectric layer, the film 106 is, for example, TiN or TaN, the film 107 is, for example, polycrystalline silicon, and the film 108 is an photo-resist layer, as shown in FIG. 5.

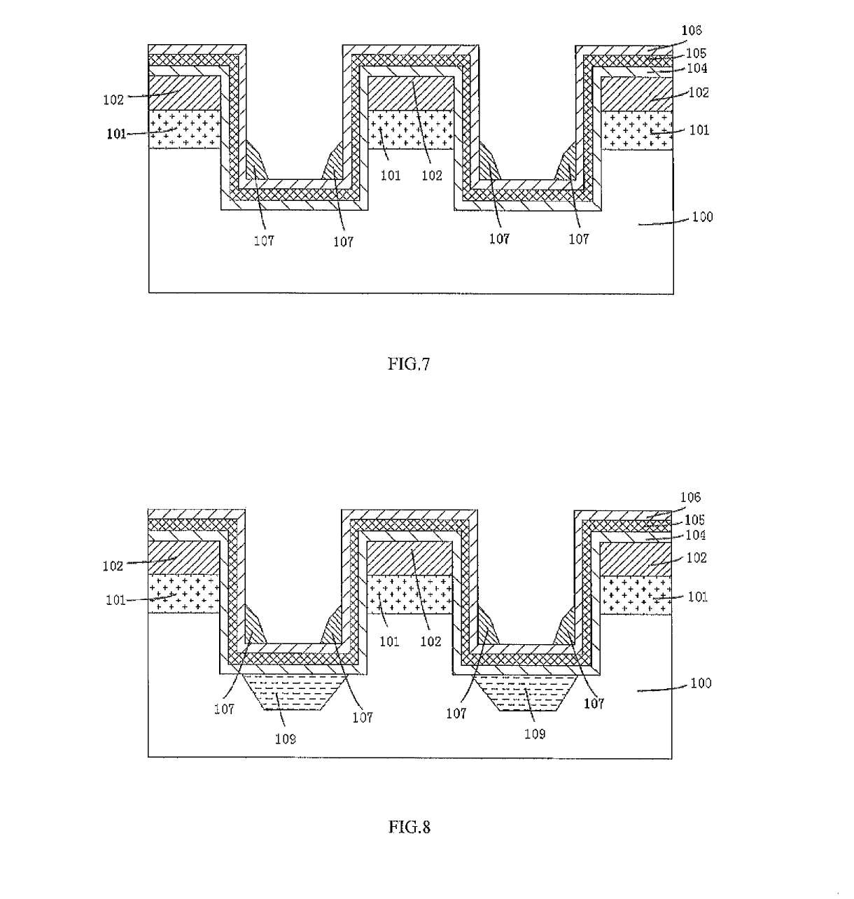

As shown in FIG. 7, etch the film 107 and remove the rest part of the film 108, FIG. 6 is the top view when carrying out the etching in this step.

Then carry out p-type ion implantation to form the doped region 109, as shown in FIG. 8.

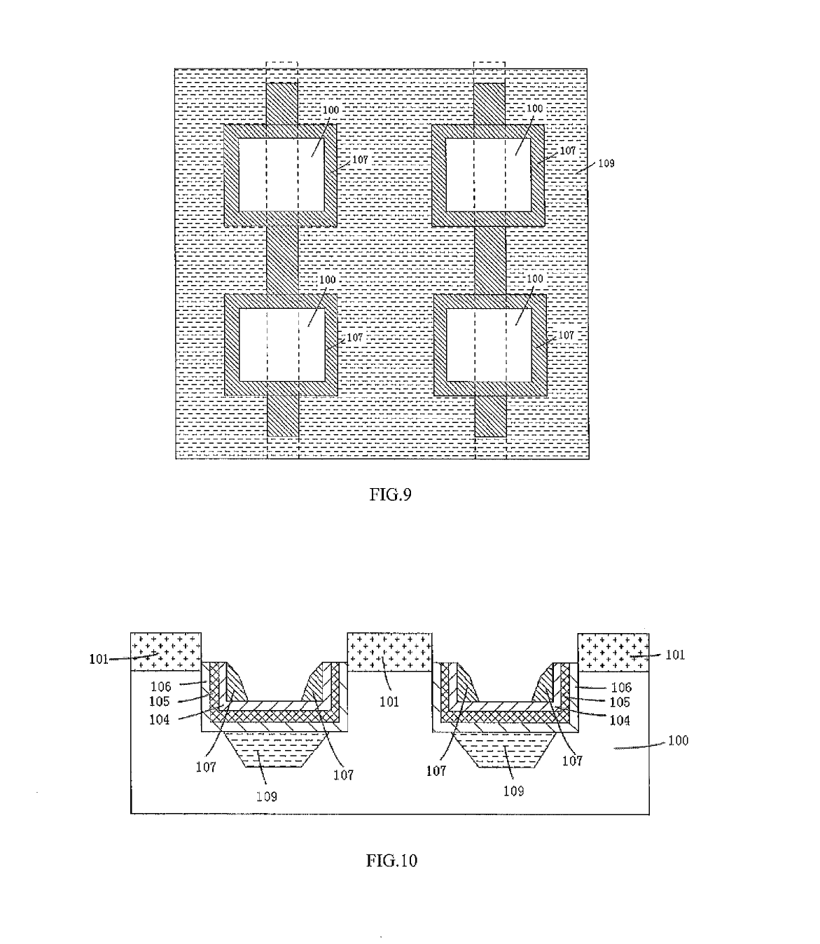

Next, as shown in FIG. 10, etch the film 104, 105 and 106. FIG. 9 is the top view when carrying out the etching.

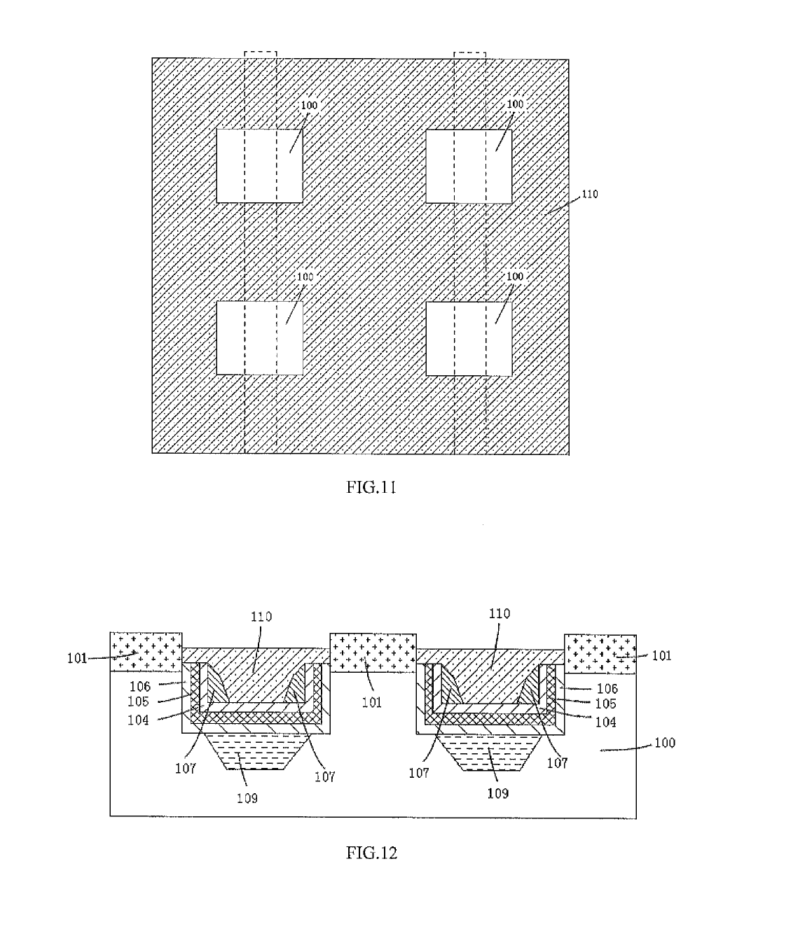

Next, form a film 110, for example, a SiO₂ layer through deposition, then etch the film 110 into a groove structure. FIG, 12 and FIG. 11 are the top views when carrying out the etching.

Next, form film 111 and 112 through deposition in turn, as shown in FIG. 13, The film 111 is made of, for example, ZnO₂, CuO or low-K material, the film 112 can be a metal, such as TiN, Ti, Ta or TaN.

Finally, etch the film 111 and the film 112 into the structure shown in FIG. 15. FIG. 14 is the top view when forming the structure shown in FIG. 15.

FIG. 16 is the equivalent electric diagram of the semiconductor memory device shown in FIG, 15. As shown in FIG. 16, the storage units 304a, 304b, 304c and 304d shown in FIG. 15 are connected with the bit line 301, wherein the said storage units are formed of the film 111, the tunneling field-effect transistors 305a, 305b, 305c and 305d are connected with the storage units 304a, 304b, 304c and 304d in series respectively, and the other end of the tunneling field-effect transistors 305a, 305b, 305c and 305d are connected with the source line 302, the word lines 303a, 303b, 303c and 303d are used to control the switches of the field-effect transistors 305a, 305b, 305c and 305d.

In this way, a semiconductor memory structure which carries out erasing, writing and reading operation on semiconductor memory through a tunneling field-effect transistor is formed.

As said above, without deviating from the spirit and scope of the present invention, many embodiments which may have a lot of big differences with each other can be acceptable. It shall be understood that, except those defined by the Claims, the present invention is not limited to the said embodiments in the Specification.

1. A semiconductor memory structure comprises at least one resistance-variable storage unit and one tunneling field-effect transistor structure which is used to operate the semiconductor memory;
wherein, the said tunneling field-effect transistor includes at least one source electrode, one drain electrode, one lightly-doped channel region and one gate electrode;
the gate of the said tunneling field-effect transistor is connected to the word line, the source electrode is connected to the source line, and the both ends of the variable resistance are connected to the bit line and the drain electrode of the said tunneling field-effect transistor respectively;
the drain region of the said tunneling field-effect transistor is located on the top of a platform structure vertical to the horizontal surface platform structure is made of semiconductor substrate material, the said source electrode is located inside the substrate outwards extended from bottom of the said platform structure, the said lightly-doped channel region is between the drain electrode and the source electrode, the said grid electrode shall cover the part below the lightly-doped channel region of the platform structure to control the current passing through the source electrode and the drain electrode in the channel region.

2. The semiconductor memory structure of claim 1, wherein the said semiconductor substrate is made of monocrystalline silicon, polycrystalline silicon or silicon-on-insulator (SOI).

3. The semiconductor memory structure of claim 1, wherein the stack of the said gate electrode comprises at least one conducting layer and one insulating layer for isolating the said conducting layer from the said semiconductor substrate, the said conducting layer is made of polycrystalline silicon, amorphous silicon, tungsten metal, titanium nitride, tantalum nitride or metal silicide, while the said insulating layer is made of SiO₂, HfO₂, HfSiO, HfSiON, SiON , Al₂O₃ or the mixture of some of them.

4. The semiconductor memory structure of claim 3, wherein the said conducting layer of the gate electrode forms a sidewall structure by surrounding the said lightly-doped channel region vertically.

5. The semiconductor memory structure of claim 1, wherein the said resistance-variable storage unit is made of phase change materials or resistance change materials.

6. The semiconductor memory structure of claim 1, wherein the said resistance-variable storage unit is connected with the source electrode or the drain electrode of the said tunneling field-effect transistor, the gate electrode of which can control the current passing through the said storage unit to realize the reading.

7. A manufacturing method of the semiconductor memory structure comprises the following steps:
providing a semiconductor substrate;
implanting on the said substrate to form a first doped type region;
forming a first layer of insulating film;
forming a active columnar region by etching the first layer of insulating film and the semiconductor substrate;
forming a high-k material dielectric layer, a conducting layer and a polycrystalline silicon layer through deposition in order;
forming a sidewall and an opening for ions implantation by etching the polycrystalline silicon layer;
implanting ions to form a second doped type region;
etching the high-k material dielectric layer, the conducting layer and the polycrystalline silicon layer, and removing the rest part of the first layer of insulating film by etching;
forming an oxide dielectric layer through deposition and forming a through-hole structure via etching it;
forming a resistance change material film and a metal layer through deposition in turn and forming a bit line through etching the resistance change material film and the metal layer.

8. The manufacturing method of claim wherein the said semiconductor substrate is made of monocrystalline silicon, polycrystalline silicon or silicon-on-insulator (SOI).

9. The manufacturing method of claim 7, wherein the first doped type is n type, the second doped type is p type, or the reverse type respectively.

10. The manufacturing method of claim 7, wherein the said first layer of insulating film is made of SiO₂, Si₃N₄ or the mixture of insulating materials of them, the said resistance change material film is ZnO₂, CuO, low-k material or GeSbTe material, and the metal layer is made of TiN, Ti, Ta or TaN.

11. The semiconductor memory structure of claim 2, wherein the said resistance-variable storage unit is made of phase change materials or resistance change materials.

12. The semiconductor memory structure of claim 2, wherein the said resistance-variable storage unit is connected with the source electrode or the drain electrode of the said tunneling field-effect transistor, the gate electrode of which can control the current passing through the said storage unit to realize the reading.

13. The semiconductor memory structure of claim 3, wherein the said resistance-variable storage unit is made of phase change materials or resistance change materials.

14. The semiconductor memory structure of claim 3, wherein the said resistance-variable storage unit is connected with the source electrode or the drain electrode of the said tunneling field-effect transistor, the gate electrode of which can control the current passing through the said storage unit to realize the reading.

15. The semiconductor memory structure of claim 4, wherein the said resistance-variable storage unit is made of phase change materials or resistance change materials.

16. The semiconductor memory structure of claim 4, wherein the said resistance-variable storage unit is connected with the source electrode or the drain electrode of the said tunneling field-effect transistor, the gate electrode of which can control the current passing through the said storage unit to realize the reading.
